(19) United States
(12) Patent Application Publication
(10) Pub. No.: US 2025/0355033 A1
(43) Pub. Date: Nov. 20, 2025

(54) SYSTEM AND METHOD FOR GROUND FAULT MONITORING

(71) Applicant: Rockwell Automation Technologies, Inc., Mayfield Heights, OH (US)

(72) Inventors: Nickolay N. Guskov, Mequon, WI (US); James J. Valasek, Port Washington, WI (US); David L. Dahl, Cedarburg, WI (US); Gary L. Skibinski, Franklin, WI (US)

(21) Appl. No.: 19/207,690

(22) Filed: May 14, 2025

Related U.S. Application Data
(60) Provisional application No. 63/649,016, filed on May 17, 2024.

(51) Int. Cl. G01R 31/08

(52) U.S. Cl. CPC G01R 31/086; G01R 31/088

(57) ABSTRACT

The present technology relates to ground fault detection in an industrial automation environment supplied by a resistively grounded power source by using voltage and frequency information measured at a grounding resistor to detect a system ground fault and identify a fault location. A ground fault monitoring system may include detection circuitry and processing circuitry. Fault detection circuitry may identify signals that include non-zero grounding resistor voltages indicative of a fault condition in the environment. The processing circuitry may receive signals from the fault detection circuitry and identify a frequency value corresponding to the fault condition. The processing circuitry determines which location corresponds to the fault condition by comparing the fault frequency value and known operational parameters of devices at various locations. Upon identifying presence and location of the fault condition, the processing circuitry may indicate the fault condition or disconnect power from the fault location.

### RELATED APPLICATIONS

This application hereby claims the benefit and priority to U.S. Provisional Application No. 63/649,016, titled “SYSTEM AND METHOD FOR GROUND FAULT MONITORING WITH FILTER AND METER,” filed May 17, 2024, which is hereby incorporated by reference in its entirety.

### TECHNICAL FIELD

Various embodiments of the present technology relate to ground fault detection systems.

### BACKGROUND

Industrial automation environments include various devices, drives, machinery, and other components, which may be driven by a power source to perform industrial and commercial processes. More particularly, the devices and systems are supplied power by a power distribution system capable of converting power from a fixed frequency power source to a different type, frequency, and amount of power and distributing the converted power downstream. Example elements of the power conversion and distribution system may include transformers, common bus drive systems, active front ends, and power converters, among other elements.

In operation of the devices in an industrial automation environment, a device, or connection between devices, may become faulty resulting in damage to the device or people nearby. Examples of such fault conditions may include short-circuits, line-to-line faults, line-to-ground faults, overcurrent, breakdown insulation of components, malfunction in monitoring components, and other conditions that may cause fire or shock. Many faults start as a line-ground fault in the environment, and they may escalate to a 3-phase fault. A solidly grounded system fault may incur equipment damage as a result of large fault current. Such systems may activate overcurrent protection devices to remove power from the industrial automation equipment causing loss of continuity of service, downtime cost and resulting in a disadvantage on their use. A single line-ground fault in a floating system theoretically should allow continuity of service, but practically, an arcing ground fault interacts with system leakage inductance and parasitic capacitance to create resonant overvoltage's that ultimately may destroy equipment. Some systems, such as high-resistance grounded (HRG) systems, overcome these disadvantages by allowing continuity of service by using a neutral grounding resistor (NGR) to provide damping to eliminate resonance overvoltage. An HRG system, if utilized, is required by the National Electric Code to monitor for fault conditions. Industrial automation environments presently employ Ground Fault Monitoring Systems (GFMS) that include ground resistors and sensors, which measure NGR voltage/current and detect a fault only based on the measured NGR voltage or current setpoint alarm level. Problematically, existing ground fault monitoring systems lack insight as to which device or connection is faulty in a power distribution network. Some ground fault monitoring systems may include numerous ground resistors and sensors at each device in the industrial automation environment to help identify fault conditions and particular locations of faults. However, such solutions are costly.

It is with respect to this general technical environment that aspects of the present disclosure have been contemplated. Furthermore, although a general environment is discussed, it should be understood that the examples described should not be limited to the general environment identified in the background.

### SUMMARY

Various embodiments of the present technology generally relate to improvements to power distribution systems, and in particular, to ground fault monitoring systems thereof, in industrial automation environments. More specifically, systems, devices, and methods are disclosed for detecting a location, and in some embodiments a particular device, in which a fault condition occurs in an industrial automation environment.

In an embodiment, a ground fault monitoring system including fault detection circuitry and processing circuitry is provided. The fault detection circuitry identifies a signal, including a non-zero voltage, indicative of a fault condition in an industrial automation environment. The fault detection circuitry provides the signal to the processing circuitry. The processing circuitry identifies a frequency value of the signal, and determines which location corresponds to the fault condition. The location may be one of several locations, such as a power supply location, a power bus location, and a load location, among other locations. To determine the location, the processing circuitry performs a comparison between the frequency value of the signal and operational parameters of devices at the locations in the industrial automation environment.

In another embodiment, a ground fault monitoring system including power supply circuitry, bus circuitry, load circuitry, and fault detection circuitry is provided. The power supply circuitry may be coupled to the bus circuitry and to the fault detection circuitry, and may be configurable to provide power (e.g., alternating current (AC)) power to the bus circuitry. The bus circuitry may be coupled to the load circuitry and to the fault detection circuitry, and may be configurable to provide power (e.g., direct current (DC) power) to the load circuitry. The load circuitry may also be coupled to the fault detection circuitry. The fault detection circuitry identifies a signal, including a non-zero voltage, indicative of a fault condition, identify a frequency value of the signal, and determine which one of the power supply circuitry, the bus circuitry, and the load circuitry corresponds to the fault condition based on performing a comparison between the frequency value and operational parameters of devices among the circuitry.

In yet another embodiment, a method of detecting faults and corresponding locations is provided. The method includes, by fault detection circuitry in an industrial automation environment, identifying a signal including a non-zero voltage indicative of a fault condition in the industrial automation environment including power supply circuitry, bus circuitry, load circuitry, and the fault detection circuitry, identifying a frequency value of the signal, and determining which one of the power supply circuitry, the bus circuitry, and the load circuitry corresponds to the fault condition based on performing a comparison between the frequency value of the signal and operational parameters of devices among the power supply circuitry, the bus circuitry, and the load circuitry.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

While multiple embodiments are disclosed, still other embodiments of the present technology will become apparent to those skilled in the art from the following detailed description, which shows and describes illustrative embodiments of the invention. As will be realized, the technology is capable of modifications in various aspects, all without departing from the scope of the present invention. Accordingly, the drawings and detailed description are to be regarded as illustrative in nature and not restrictive.

### BRIEF DESCRIPTION OF THE DRAWINGS

Many aspects of the disclosure can be better understood with reference to the following drawings. The components in the drawings are not necessarily drawn to scale. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1 illustrates an example operating environment in accordance with some embodiments of the present technology.

FIG. 2 illustrates an example block diagram of a ground fault monitoring system in accordance with some embodiments of the present technology.

FIG. 3 illustrates a series of steps for detecting faults in an industrial automation environment in accordance with some embodiments of the present technology.

FIGS. 4A, 4B, and 4C illustrate exemplary graphical representations including measurements captured in a ground fault monitoring system in accordance with some embodiments of the present technology.

FIG. 5 illustrates an example block diagram of a ground fault monitoring system in accordance with some embodiments of the present technology.

FIG. 6 illustrates an example block diagram of a ground fault monitoring system in accordance with some embodiments of the present technology.

FIG. 7 illustrates an example block diagram of a ground fault monitoring system in accordance with some embodiments of the present technology.

FIGS. 8A, 8B, and 8C illustrate example block diagrams of ground fault monitoring systems in accordance with some embodiments of the present technology.

FIGS. 9 and 10 illustrate example graphical representations related to noise filtering in a ground fault monitoring system in accordance with some embodiments of the present technology.

FIG. 11 illustrates an example computing system used in some embodiments of the present technology.

The drawings have not necessarily been drawn to scale. Similarly, some components or operations may not be separated into different blocks or combined into a single block for the purposes of discussion of some of the embodiments of the present technology. Moreover, while the technology is amendable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

Technology is disclosed herein that mitigates the problems discussed above with respect to ground fault monitoring systems in industrial automation environments by measuring signals from an industrial automation environment to detect a presence of a fault condition and measuring frequency of the signals to detect a location of the fault condition.

In industrial or commercial environments, devices such as variable-speed drives, variable-frequency drives, motors, belts, and the like, are driven by power distribution systems to perform respective functions. A power source, such as an alternating current (AC) power supply (e.g., AC mains electricity) provides the power to the power distribution system, which can be converted and distributed by a common bus drive system of the power distribution system to various devices in an environment. Transformers are also used to change utility grid high voltage magnitude down to a utilization voltage required for the devices in the environment. Distribution transformer secondary windings are typically connected in a delta or wye configuration. Secondary winding options are typically used in a Floating Ground System (i.e., a configuration that does not include a direct connection to earth ground) or Solidly Ground System (i.e., a configuration in which a wye neutral point is directly connected to earth ground to establish a newly derived reference ground), or a Resistive Grounded System (i.e., a configuration where a wye neutral point is connected to a neutral grounding resistor (NGR) and to earth ground).

When dealing with large voltages and currents, and industrial and electrical machinery, precautions must be taken to avoid damage to the devices and operators working in the environment caused by fault conditions, such as overloads, short-circuits, breakdown insulation of components, and other fault conditions that may cause fire or electrical harm. Accordingly, the environments include ground fault monitoring systems to detect fault conditions and disconnect power to the devices and systems to prevent, or at least reduce, potential risk.

Ground fault monitoring systems often include an assembly including an impedance (e.g., a neutral grounding resistor (HRG)) and a sensor. The impedance can draw current from the power distribution system and/or the loads (e.g., motors, variable-frequency drives), and the sensor can measure voltage of the signal across the impedance. While such existing ground fault monitoring systems can detect the presence of a fault condition within an environment, the ground fault monitoring systems fail to pinpoint a location or responsible device of the fault condition without complex and costly designs or without manual effort. By way of example, upon detecting a fault condition, an operator may manually disconnect, test, and re-connect each device to test the devices and detect the device responsible for the fault condition. This, however, results in downtime and manual effort, ultimately increasing cost and decreasing efficiency of a system.

By way of another example, a ground fault monitoring system may include numerous fault detection assemblies coupled to each device in the environment. However, this is costly as many impedances and sensors may be required if the environment includes a large number of devices. Additionally, in such environment including a plurality of devices, some devices may be co-located in the same area, but some may be located remotely from others, such as on different floors or in different rooms. As such, an operator may still spend time traveling to each location in an environment to monitor for fault conditions.

To address these issues, a ground fault detection system is described herein that includes a filter, a voltage sensor, and a frequency sensor, among other elements, to detect faults and identify in which location within an industrial automation environment a fault has occurred. For example, the ground fault detection system may identify the location as a component of a power supply, a component of a power conversion and distribution system, or a load driven by the power conversion and distribution system. The ground fault detection system can store operational parameters of each of the components in the industrial automation environment. Upon detecting a fault, the ground fault detection system measures the frequency of a received signal and performs a comparison between the frequency and the operational parameters of the components. In various embodiments, the frequency sensor selected may be capable of detecting differences in frequency between signals having low-frequency values, including frequencies in the single digits and greater, for example. The ground fault detection system determines the location of the fault condition based on a match between the frequency and the operational parameters.

In an embodiment, a ground fault monitoring system including fault detection circuitry and processing circuitry is provided. The fault detection circuitry identifies a signal, including a non-zero voltage, indicative of a fault condition in an industrial automation environment. The fault detection circuitry provides the signal to the processing circuitry. The processing circuitry identifies a frequency value of the signal, and determines which location corresponds to the fault condition. The location may be one of several locations, such as a power supply location, a power bus location, and a load location, among other locations. To determine the location, the processing circuitry performs a comparison between the frequency value of the signal and operational parameters of devices at the locations in the industrial automation environment.

In another embodiment, a ground fault monitoring system including power supply circuitry, bus circuitry, load circuitry, and fault detection circuitry is provided. The power supply circuitry may be coupled to the bus circuitry and to the fault detection circuitry, and may be configurable to provide power (e.g., alternating current (AC)) power to the bus circuitry. The bus circuitry may be coupled to the load circuitry and to the fault detection circuitry, and may be configurable to provide power (e.g., direct current (DC) power) to the load circuitry. The load circuitry may also be coupled to the fault detection circuitry. The fault detection circuitry identifies a signal, including a non-zero voltage, indicative of a fault condition, identify a frequency value of the signal, and determine which one of the power supply circuitry, the bus circuitry, and the load circuitry corresponds to the fault condition based on performing a comparison between the frequency value and operational parameters of devices among the circuitry.

In yet another embodiment, a method of detecting faults and corresponding locations is provided. The method includes, by fault detection circuitry in an industrial automation environment, identifying a signal including a non-zero voltage indicative of a fault condition in the industrial automation environment including power supply circuitry, bus circuitry, load circuitry, and the fault detection circuitry, identifying a frequency value of the signal, and determining which one of the power supply circuitry, the bus circuitry, and the load circuitry corresponds to the fault condition based on performing a comparison between the frequency value of the signal and operational parameters of devices among the power supply circuitry, the bus circuitry, and the load circuitry.

Advantageously, the disclosed systems, devices, and methods can provide for fault condition monitoring and fault location detection in an industrial automation environment without implementing multiple fault detection sensors distributed throughout the industrial automation environment, thereby reducing the cost of the fault detection system disclosed herein. The systems, devices, and methods can filter noise of signals obtained from various devices operating in the industrial automation environment, thereby increasing accuracy with which the fault location is determined. Detecting the fault location may not only improve safety and reduce risk presented by fault conditions, but also reduce manual effort and time required to pinpoint a fault location after detecting a fault condition as in existing solutions.

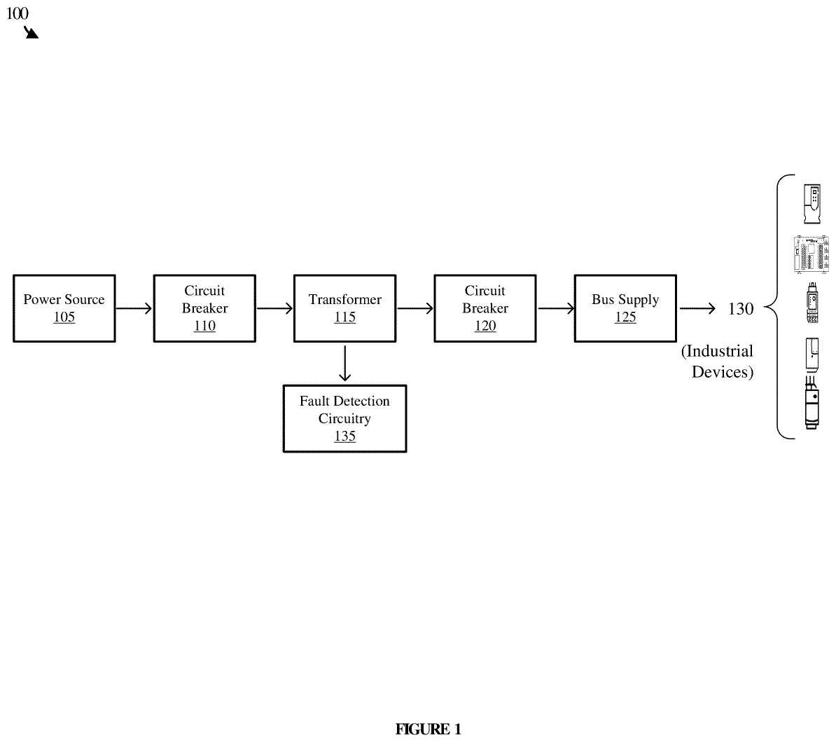

Turning now to the Figures, FIG. 1 illustrates an example operating environment in accordance with some embodiments of the present technology. FIG. 1 includes operating environment 100, which is representative of an environment in which industrial and commercial processes may be performed. Operating environment 100 includes power source 105, circuit breaker 110, transformer 115, circuit breaker 120, bus supply 125, industrial devices 130, and fault detection circuitry 135.

Power source 105 is representative of a power supply capable of providing power to various elements of operating environment 100. For example, power source 105 is an alternating current (AC) power source, such as AC mains electricity, that generates three-phase AC power and provides the AC power to transformer 115 via circuit breaker 110.

Transformer 115 includes a power transformer capable of stepping up or stepping down voltage levels from power source 105 and providing converted voltage to bus supply 125 via circuit breaker 120. In various embodiments, transformer 115 includes a connection configuration such that transformer 115 can receive three-phase AC power from power source 105 and providing three-phase AC power to bus supply 125. Transformer 115 may additionally include a neutral terminal coupled to fault detection circuitry 135. Examples of the connection configurations include—but are not limited to—a delta-wye configuration, a wye-delta configuration, a delta-delta configuration, a wye-wye configuration, a zigzag configuration, and an open delta configuration, among other types of transformer configurations, including multi-phase transformers and assemblies (e.g., a six-pulse transformer assembly, a twelve-pulse transformer assembly, an eighteen-pulse transformer assembly, a twenty-four-pulse transformer assembly).

Circuit breakers 110 and 120 are representative of devices capable of providing fault protection in operating environment 100. Circuit breaker 110 is coupled to power source 105 and transformer 115 and provides overload protection to power source 105 and transformer 115 in the event of a fault condition of either device (e.g., overcurrent, short-circuit, breaking insulation). Circuit breaker 120 is coupled to transformer 115 and bus supply 125 and provides overload protection to transformer 115 and bus supply 125 in the event of a fault condition of either device.

In various embodiments, circuit breakers 110 and 120 are representative of devices capable of allowing current flow in an on state and preventing current flow in an off state. By way of example, circuit breakers 110 and 120 are solid-state circuit breakers that include controllable switches to transition between modes and allow or prevent current flow from power source 105 to transformer 115, and from transformer 115 to bus supply 125, respectively. In another example, circuit breakers 110 and 120 are electromechanical circuit breakers capable of providing similar functionality. Other types of circuit breakers, as well as combinations and variations thereof may be used.

Bus supply 125 is representative of circuitry capable of managing and distributing power from power source 105 (via transformer 115) to industrial devices 130. In some embodiments, bus supply 125 may be a direct current (DC) bus supply that converts AC power, provided to bus supply 125 by transformer 115, to DC power and provides DC power to industrial devices 130. In some embodiments, bus supply 125 may be an active front end (AFE) that drives AC power from transformer 115 to industrial devices 130. Other configurations, including combinations and variations thereof, may be contemplated, such as combinations of DC and AC common bus supplies, common bus supplies coupled to multi-pulse rectifiers, and the like.

Industrial devices 130 include various types of industrial and commercial devices that may be used to perform respective processes in operating environment 100. For example, industrial devices 130 may include one or more of variable-speed drives, motors, conveyer belts, circuit devices, programmable logic controllers (PLCs), relays, sensors, and more. Various components of industrial devices 130 may be coupled together via wired or wireless connections. Based on respective processes, industrial devices 130 may require different amounts of power and may operate at different frequencies. Such information may be referred to as operational parameters of industrial devices 130, which may be stored by fault detection circuitry 135.

Fault detection circuitry 135 is representative of a ground fault monitoring system coupled to transformer 115. In various embodiments, fault detection circuitry 135 includes circuitry capable of measuring ground fault voltage and frequency signals from components of operating environment 100 via transformer 115, detecting an occurrence of a fault condition within operating environment 100 based on the signals, and identifying the location (e.g., a device, a group of devices) at which the fault condition occurs. In particular, fault detection circuitry 135 includes a high-resistance ground (HRG) assembly, a ground fault filter, one or more sensors (e.g., a voltmeter, a frequency meter), and processing circuitry.

In operation, fault detection circuitry 135 receives signals at the HRG assembly of fault detection circuitry 135 via a neutral terminal of transformer 115 and filters noise (e.g., noise from high pulse width modulation switching frequency, cable noise, system common noise) of the signals via the ground fault filter. Fault detection circuitry 135 identifies values of the filtered signals using sensors. For example, fault detection circuitry 135 identifies voltage values of the signals using a voltmeter and frequency values of the signals using a frequency meter.

Next, fault detection circuitry 135 performs a comparison of the voltage values to a threshold voltage to determine whether the signals indicate a fault condition within operating environment 100. If fault detection circuitry 135 detects a fault condition, fault detection circuitry 135 performs a comparison between the frequency values of the signals to operational parameters of industrial devices 130, such as operational frequency, to determine a match. Upon identifying a match, fault detection circuitry 135 determines the device responsible for the fault condition and the location of the device with respect to other devices in operating environment 100. Fault detection circuitry 135 may additionally provide an indication (e.g., a notification, an alert, an alarm signal, a visual indicator on a user interface) of the fault condition, the device, and the location of the fault condition.

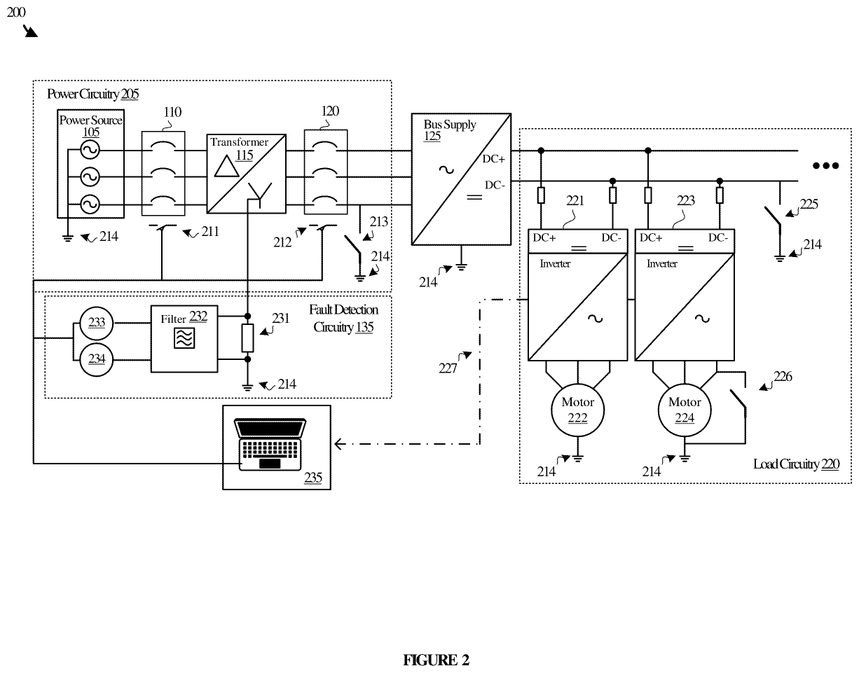

In some embodiments, operating environment 100 may include fewer, additional, or different elements, as well as different configurations of elements, and combinations and variations thereof. Exemplary block diagrams of elements of operating environment 100 including more detailed components and configurations thereof are shown and described below in FIGS. 2, 5, and 6.

Referring next to FIG. 2, FIG. 2 illustrates an example operating environment in accordance with some embodiments of the present technology, which references elements of operating environment 100 of FIG. 1. FIG. 2 shows operating environment 200, which is representative of an environment in which industrial and commercial processes may be performed. Operating environment 200 includes circuitry capable of generating power, converting and distributing the power, and performing respective operations using the power. Operating environment 200 also includes circuitry capable of detecting fault conditions within the circuitry. More specifically, operating environment 200 includes power circuitry 205, bus supply 125, fault detection circuitry 135, load circuitry 220, and processing circuitry 235.

Power circuitry 205 is representative of circuitry configurable to generate and convert power for use by various elements of operating environment 200. Power circuitry 205 includes power source 105, circuit breaker 110, transformer 115, and circuit breaker 120. Additionally, power circuitry 205 includes switches 211 and 212, which may be utilized to connect or disconnect power circuitry 205 to and from bus supply 125, respectively. Accordingly, switches 211 and 212 may be controlled to allow or prevent current flow from power circuitry 205 to and from bus supply 125, respectively.

Power source 105 is capable of providing three-phase AC power to transformer 115 via circuit breaker 110. Power source 105 includes three terminals, each coupled to a respective input terminal of circuit breaker 110. In particular, a first terminal of power source 105 is coupled to a first input terminal of circuit breaker 110 and provides a first phase of the three-phase AC power to circuit breaker 110, a second terminal of power source 105 is coupled to a second input terminal of circuit breaker 110 and provides a second phase of the three-phase AC power to circuit breaker 110, and a third terminal of power source 105 is coupled to a third input terminal of circuit breaker 110 and provides a third phase of the three-phase AC power to circuit breaker 110. Each terminal of power source 105 is also coupled to ground node 214.

Circuit breaker 110 includes the three input terminals coupled to respective terminals of power source 105 and includes three output terminals each coupled to a respective one of three input terminals of transformer 115. Circuit breaker 110 also includes a terminal coupled to switch 211. Switch 211 may be representative of a shunt switch that controls current flow through circuit breaker 110. For example, while switch 211 is closed, current can flow from power source 105 to transformer 115. If switch 211 is opened, such as in response to a fault condition at circuit breaker 110 or power source 105, circuit breaker 110 shuts off and current flow is prevented from power source 105 to transformer 115.

Transformer 115 may be representative of a transformer having a delta-wye connection configuration. In some embodiments, transformer 115 includes a Y-connected primary side coupled to three output terminals of circuit breaker 110. In some embodiments, transformer 115 instead includes a Y-connected secondary side. Additionally, transformer 115 includes a neutral terminal, which may be coupled to fault detection circuitry 135. In such embodiments where transformer 115 includes a Y-connected primary side, transformer 115 includes three input terminals coupled to the output terminals of circuit breaker 110, and transformer 115 includes three output terminals each coupled to a respective one of three input terminals of circuit breaker 120, and a neutral terminal coupled to fault detection circuitry 135. In some embodiments, transformer 115 may be representative of another type of transformer, a transformer having a different connection configuration, or a transformer included in a multi-pulse configuration.

Circuit breaker 120 includes the three input terminals coupled to respective terminals of transformer 115 and includes three output terminals each coupled to a respective one of three input terminals of bus supply 125. Circuit breaker 120 also includes a terminal coupled to switch 212. Switch 212, like switch 211, may be representative of a shunt switch that controls current flow through circuit breaker 120. For example, while switch 212 is closed, current can flow from transformer 115 to bus supply 125. If switch 212 is opened, such as in response to a fault condition at circuit breaker 120 or transformer 115, circuit breaker 120 shuts off and current flow is prevented from transformer 115 to bus supply 125.

One of the output terminals of circuit breaker 120 may additionally be coupled to ground node 214. A fault detection area 213 is located between the output terminal of circuit breaker 120 and ground node 214, at which a fault within power circuitry 205 may be detected.

Bus supply 125 includes the three input terminals coupled to respective terminals of circuit breaker 120, a terminal coupled to ground node 214, and two output terminals coupled to load circuitry 220. Accordingly, bus supply 125 receives three-phase AC power as an input and provides DC power as an output to load circuitry 220. In some embodiments, bus supply 125, instead, outputs three-phase AC power to load circuitry 220.

Load circuitry 220 is representative of one or more industrial devices operable to perform respective functionality based on receiving power from bus supply 125. Examples of the industrial devices include variable-speed drives, motors, conveyer belts, circuit devices, programmable logic controllers (PLCs), relays, sensors, and more. In various examples, the industrial devices may form an AC or DC common system that shares power from bus supply 125. As shown in operating environment 200, a first load includes drive 221 and motor 222, and a second load includes drive 223 and motor 224. Additional, fewer, or different loads may be included in load circuitry 220.

Drives 221 and 223 are representative of variable-frequency drives configurable to receive the DC power from bus supply 125 and convert the DC power to three-phase AC power for use by motors 222 and 224, respectively. As such, each of drives 221 and 223 includes two input terminals coupled to the two output terminals of bus supply 125 and three output terminals coupled to three input terminals of motors 222 and 224, respectively.

Motors 222 and 224 are representative of AC motors configurable to drive other loads in an industrial automation drive (not shown). Motors 222 and 224 operate at specific frequencies and speeds based on the AC power fed to the motors by drives 221 and 223, respectively. In some embodiments, such operational parameters of motors 222 and 224 are different from one another. In some embodiments, the operational parameters of motors 222 and 224 may be the same. Motors 222 and 224 may each also include a terminal coupled to ground node 214.

Load circuitry 220 may additionally include fault detection areas 225 and 226, representative of locations within load circuitry 220 at which a fault within load circuitry 220 can be detected

Fault detection circuitry 135 is also included in operating environment 200 to detect a presence and a location of a ground fault within power circuitry 205, bus supply 125, and load circuitry 220, such as at one or more of fault detection areas 213, 225, and 226. Fault detection circuitry 135 includes high-resistance ground (HRG) assembly 231, filter 232, voltmeter 233, and frequency meter 234. Fault detection circuitry 135 may include processing circuitry 235. Alternatively, processing circuitry 235 may be external relative to fault detection circuitry 135.

HRG assembly 231 is representative of one or more high-resistance components positioned between the neutral node of transformer 115 and ground node 214 to limit fault current and function as a source for detecting ground fault voltage and frequency signals. HRG assembly 231 includes a first terminal coupled to the neutral terminal of transformer 115 and a second terminal coupled to ground node 214.

Filter 232 is representative of circuitry capable of receiving ground fault voltage and frequency signals captured across HRG assembly 231 and filtering noise from the signals received at HRG assembly 231. Filter 232 is coupled to the first terminal of HRG assembly 231 and to the second terminal of HRG assembly 231 to receive the signals across HRG assembly 231. In various embodiments, filter 232 is configured to filter switching frequency noise from such signals, which may improve detection of voltage values and frequency values of such signals during fault detection processes. For example, filter 232 filters high pulse width modulation switching frequency noise, among other types of noise, including portions of signals having different frequencies.

Voltmeter 233 and frequency meter 234 are representative of sensors capable of measuring voltage and frequency values of the ground fault voltage and frequency signals filtered by filter 232. In various embodiments, frequency meter 234 is representative of a type of frequency detection sensor capable of detecting frequency values of a signal within a frequency range, and that is discrete relative to voltmeter 233. In some embodiments, the frequency range detectable by frequency meter 234 includes low-frequency values, such as frequencies as low as five Hertz (Hz), for example. Additional or different frequency values and ranges thereof may also be detected by frequency meter 234.

Processing circuitry 235 is representative of one or more processors, processing cores, or processing circuits capable of receiving the frequency and voltage values of the ground fault signals from voltmeter 233 and frequency meter 234, respectively, and detecting a presence and a location of a fault condition based on the values. Additionally, processing circuitry 235 may be capable of controlling operations of circuit breakers 110 and 120, among other elements of operating environment 200, via switches 211 and 212, respectively. Examples of such processor(s) of processing circuitry 235 include—but are not limited to—microcontrollers, microprocessors, general purpose processing units, central processing units (CPUs), graphical processing units (GPUs), digital signal processors (DSPs), application specific processors or circuits (e.g., ASICs), and logic devices (e.g., FPGAs), as well as any other type of processing device, combinations, or variations thereof.

To detect the presence of a fault condition in operating environment 200, processing circuitry 235 performs a comparison between the voltage values and a threshold voltage value and identifies a fault condition based on the results of the comparison. Similarly, to detect the location of the fault condition, such as one of power circuitry 205, bus supply 125, and load circuitry 220, processing circuitry 235 performs a comparison between the frequency values and operational parameters of each of the devices in operating environment 200. For example, devices of power circuitry 205 may operate at a frequency of approximately 60 Hz, bus supply 125 may operate at a frequency of approximately 180 Hz, and one or more motors of load circuitry 220 may operate a frequency of approximately 20 Hz, each of which may be indicated in a data structure accessible by processing circuitry 235 (e.g., in memory), or additionally or alternatively, by frequency indications 227 provided to processing circuitry 235 by each of the devices in operating environment 200. Thus, for a given frequency value, processing circuitry 235 may correlate the fault condition with a matching operational frequency of a device in operating environment 200 and determine that the fault condition occurs at a location associated with the device.

Upon detecting a fault and the location of the fault, processing circuitry 235 may output an indication of the fault and the location of the fault. This may entail processing circuitry 235 displaying an indication (e.g., visual indication, graphical indication) of the fault and its location on a user interface of a computer, tablet, or smart phone, providing an alert to a user via the user interface or via a wireless connection to another computer, tablet, or smart phone, or the like. Additionally, processing circuitry 235 may trigger a disconnect option for power circuitry 205, such as opening switches 211 and/or 212 to prevent current flow from power circuitry 205 to bus supply 125.

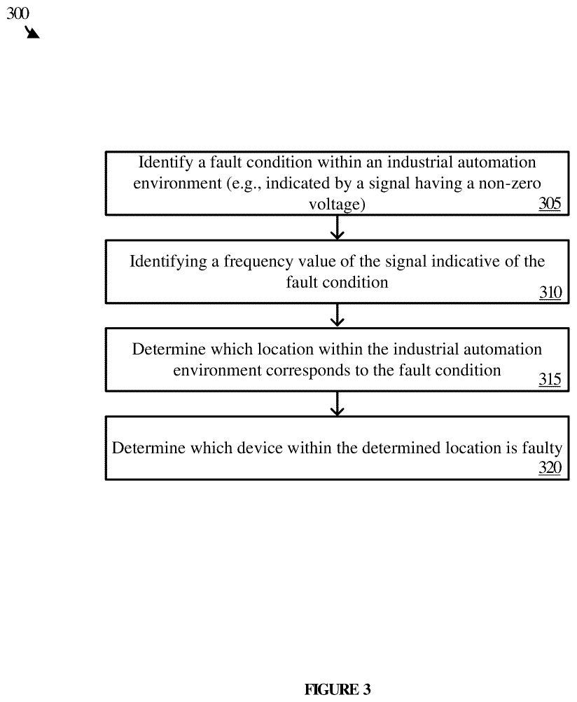

FIG. 3 illustrates a series of steps for detecting faults in an industrial automation environment in accordance with some embodiments of the present technology. FIG. 3 includes method 300, which references elements of operating environment 100 and system 200 of FIGS. 1 and 2, respectively. In various examples, method 300 may be implemented in hardware, software, and/or firmware, as well as combinations and variations thereof. For example, method 300 may be implemented by fault detection circuitry 135, or processing circuitry 235 thereof, of FIGS. 1 and 2, respectively.

In operation 305, processing circuitry 235 identifies a presence of a fault condition in an industrial automation environment (e.g., operating environment 100, operating environment 200). In various embodiments, fault detection circuitry 135 includes an HRG assembly 231 coupled between a reference ground terminal, ground node 214, and a neutral terminal of transformer 115. In such a configuration, signals flow from the neutral node of transformer 115 to ground node 214 through HRG assembly 231 from various locations within the industrial automation environment during operation of components in the industrial automation environment (i.e., while provided is provided to various components in the industrial environment by power source 105). Such signals may include values indicative of the presence of the fault condition.

The signals flowing across HRG assembly 231 are captured by filter 232, filtered by filter 232 to reduce noise in the signals, and measured by voltmeter 233 and frequency meter 234. Processing circuitry 235 identifies the voltage values of the signals measured by voltmeter 233 and identifies the presence of the fault condition based on the voltage values. For example, processing circuitry 235 performs a comparison between the measured voltage values and a threshold voltage value. Processing circuitry 235 determines the presence of the fault condition based on the results of the comparison indicating a breach of the threshold voltage value.

In operation 310, processing circuitry 235 identifies a frequency value of the signals. For example, processing circuitry 235 identifies a frequency value of the signals as measured by frequency meter 234. In various embodiments, frequency meter 234 is representative of a type of frequency detection sensor capable of detecting frequency values of a signal within a frequency range. In some embodiments, the frequency range detectable by frequency meter 234 includes low-frequency values, such as frequencies as low as five Hz. Additional or different frequency values and ranges thereof may also be detected by frequency meter 234.

In operation 315, processing circuitry 235 determines which location within the industrial automation environment corresponds to the fault condition. In some embodiments, the locations correspond to groups of devices or systems within the environment, such as power circuitry 205, bus supply 125, and load circuitry 220. In some embodiments, the locations may additionally, or instead, correspond to physical locations in which a device or group of devices is located within the environment. Processing circuitry 235 determines the location of the fault condition based on the frequency value measured by frequency meter 234. In various embodiments, this may entail processing circuitry 235 performing a comparison between the frequency value and operational parameters of the devices within the environment. More specifically, processing circuitry 235 may store information about the devices or groups of the devices associated with a given location, such as operating voltage, operating frequency, device type, device location, and the like. Processing circuitry 235 compares the frequency value to such information to find a match. Upon determining a match between an operating frequency of a device and the frequency value of the signals, processing circuitry 235 determines the location of the fault condition. Optionally, in operation 320, processing circuitry 235 additionally determines a particular device responsible for the fault condition as well as a physical location of the faulty device based on the result of the comparison.

In some embodiments, some devices in the industrial automation environment may include the same or similar operational parameters, such as operating frequency. In such embodiments, processing circuitry 235 may determine multiple possible locations associated with the fault condition. Optionally, processing circuitry 235 may change the operational parameters of at least one of the devices among the possible faulty devices, then processing circuitry 235 may perform steps of operations 310, 315, and 320 again to eliminate one or more of the possible locations and determine the location and/or device responsible for the fault condition.

By way of example, motors 222 and 224 of operating environment 200 may both operate at approximately 50 Hz. Upon identifying a frequency value of a signal across HRG assembly 232 of approximately 50 Hz, processing circuitry 235 may determine that the location of the fault condition corresponds to load circuitry 220 assuming no other components in operating environment 200 operate at such a frequency value. Processing circuitry 235 might not be able to positively determine which device within load circuitry 220 is faulty based on the operating frequencies of motors 222 and 224 and the measured frequency value. As such, processing circuitry 235 may change the operating frequency of motor 224 to approximately 51 Hz (or some other value) while continuing to operate motor 222 at 50 Hz. Then, processing circuitry 235 identifies the frequency value of the signal across HRG assembly 232 again. If the frequency value remains at 50 Hz,, processing circuitry 235 can determine that motor 222 is not faulty. However, if the frequency value of the signal increases to approximately 51 Hz,, processing circuitry 235 can determine that motor 224 is faulty.

Upon determining the presence of the fault condition, processing circuitry 235 may additionally disconnect power circuitry 205 from bus supply 125 such that current flow is prevented to the faulty device(s). In various embodiments, processing circuitry 235 provides signals to switch 211 and/or switch 212 to disconnect power circuitry 205 from bus supply 125. Processing circuitry 235 may connect power circuitry 205 to transformer 115 and to bus supply 125 after the fault condition is resolved.

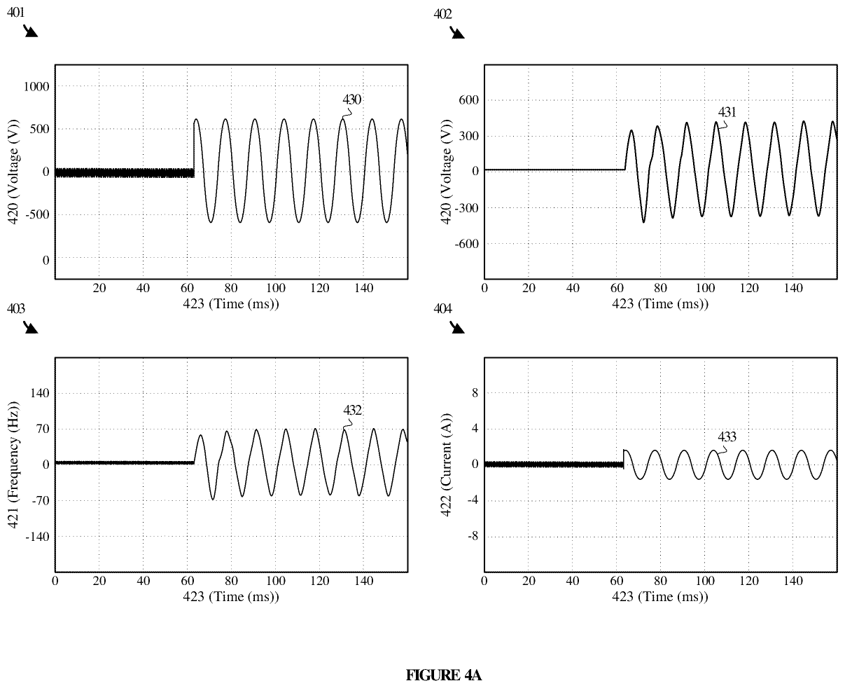

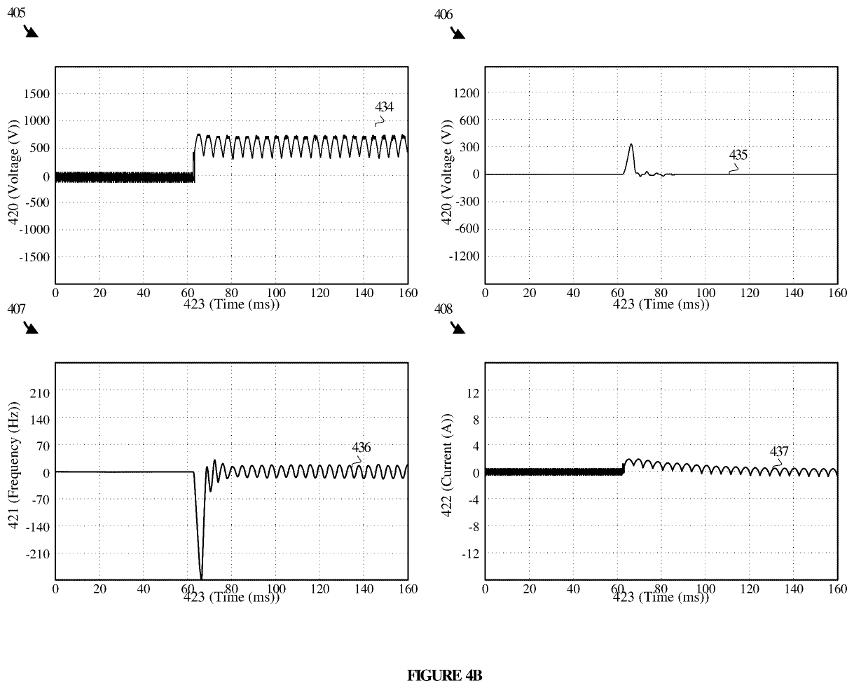

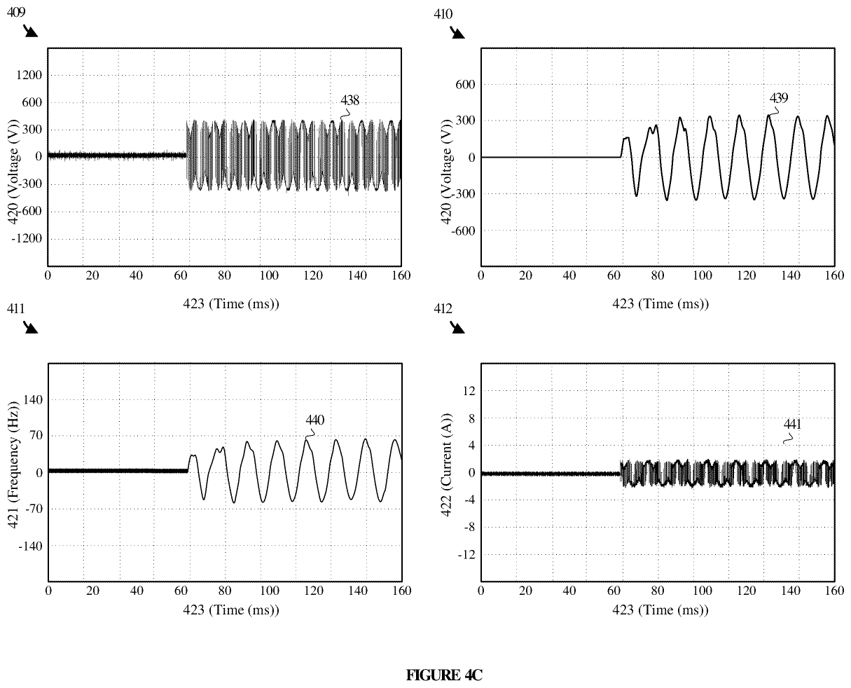

FIGS. 4A, 4B, and 4C illustrate exemplary graphical representations including measurements captured in a ground fault monitoring system in accordance with some embodiments of the present technology. FIG. 4A includes graphical representations 401, 402, 403, and 404. FIG. 4B includes graphical representations 405, 406, 407, and 408. FIG. 4C includes graphical representations 409, 410, 411, and 412. Each graphical representation shows a waveform representative of a signal captured across a high-resistance ground (HRG) assembly, such as HRG assembly 231 of fault detection circuitry 135. Some waveforms correspond to voltage 420 with respect to time 423, some waveforms correspond to frequency 421 with respect to time 423, and some waveforms correspond to current 422 with respect to time 423. Notably, a ground fault condition may be applied around 60 milliseconds with respect to time 423 as illustrated in each graphical representation.

Referring first to FIG. 4A, graphical representation 401 includes waveform 430 representative of an unfiltered signal measured at HRG assembly 231 with respect to voltage 420 and time 423, graphical representation 402 includes waveform 431 representative of a signal measured at an output of filter 232 with respect to voltage 420 and time 423 (i.e., a filtered signal), graphical representation 403 includes waveform 432 representative of a signal measured at an output of filter 232 with respect to frequency 421 and time 423, and graphical representation 404 includes waveform 433 representative of a signal measured at HRG assembly 231 with respect to current 422 and time 423.

As shown by graphical representations 401 and 402, and graphical representation 404, a signal received by fault detection circuitry 135 includes non-zero voltage values, and non-zero current values, respectively, for a duration beginning around 60 milliseconds. Such non-zero values may indicate the presence of a fault condition within an industrial automation environment (e.g., operating environment 100, operating environment 200). In operation, fault detection circuitry 135 measures the values of the non-zero voltage and current of respective waveforms to determine whether the values exceed respective voltage and current threshold values. If the values do exceed the threshold values, fault detection circuitry 135 determines the presence of a fault condition.

In such instances where fault detection circuitry 135 determines the presence of a fault condition, fault detection circuitry 135 measures the frequency values of the signal across the HRG assembly to determine the frequency 421 of the signal at the same time, with respect to time 423, corresponding to the spike in voltage or current of respective waveforms. As shown in waveform 432 of graphical representation 403, waveform 432 indicates a frequency 421 of approximately 60 Hz at the corresponding time. Accordingly, fault detection circuitry 135 performs a comparison between the frequency value and operational parameters of devices within the industrial automation environment (e.g., industrial devices 130) to determine a device operating at the frequency value (approximately 60 Hz), and a location of the device, corresponding to the fault condition. For example, the frequency value of waveform 432 may indicate that a fault has occurred at the AC line side of a ground fault monitoring system, such as at fault detection area 213 of operating environment 200.

Referring next to FIG. 4B, graphical representation 405 includes waveform 434 representative of a signal measured at HRG assembly 231 with respect to voltage 420 and time 423, graphical representation 406 includes waveform 435 representative of a signal measured at an output of filter 232 with respect to voltage 420 and time 423, graphical representation 407 includes waveform 436 representative of a signal measured at an output of filter 232 with respect to frequency 421 and time 423, and graphical representation 408 includes waveform 437 representative of a signal measured at HRG assembly 231 with respect to current 422 and time 423.

As shown by graphical representations 405 and 406, and graphical representation 408, a signal received by fault detection circuitry 135 includes non-zero voltage values, and non-zero current values, respectively, for a duration beginning around 60 milliseconds. Such non-zero values may indicate the presence of a fault condition within an industrial automation environment. In operation, fault detection circuitry 135 measures the values of the non-zero voltage and current of respective waveforms to determine whether the values exceed respective voltage and current threshold values. If the values do exceed the threshold values, fault detection circuitry 135 determines the presence of a fault condition.

In such instances where fault detection circuitry 135 determines the presence of a fault condition, fault detection circuitry 135 measures the frequency values of the signal across the HRG assembly to determine the frequency 421 of the signal at the same time, with respect to time 423, corresponding to the spike in voltage or current of respective waveforms. As shown in waveform 436 of graphical representation 407, waveform 436 indicates a frequency 421 of approximately 180 Hz at the corresponding time. Accordingly, fault detection circuitry 135 performs a comparison between the frequency value and operational parameters of devices within the industrial automation environment (e.g., industrial devices 130) to determine a device operating at the frequency value (approximately 180 Hz, e.g., for a 6-pulse diode bridge or Active Front End converter), and a location of the device, corresponding to the fault condition. For example, the frequency value of waveform 436 may indicate that a fault has occurred at the bus side of a ground fault monitoring system, such as at fault detection area 225 of operating environment 200.

Referring next to FIG. 4C, graphical representation 409 includes waveform 438 representative of a signal measured at HRG assembly 231 with respect to voltage 420 and time 423, graphical representation 410 includes waveform 439 representative of a signal measured at an output of filter 232 with respect to voltage 420 and time 423, graphical representation 411 includes waveform 440 representative of a signal measured at an output of filter 232 with respect to frequency 421 and time 423, and graphical representation 412 includes waveform 441 representative of a signal measured at HRG assembly 231 with respect to current 422 and time 423.

As shown by graphical representations 409 and 410, and graphical representation 412, a signal received by fault detection circuitry 135 includes non-zero voltage values, and non-zero current values, respectively, for a duration beginning around 60 milliseconds. Such non-zero values may indicate the presence of a fault condition within an industrial automation environment. In operation, fault detection circuitry 135 measures the values of the non-zero voltage and current of respective waveforms to determine whether the values exceed respective voltage and current threshold values. If the values do exceed the threshold values, fault detection circuitry 135 determines the presence of a fault condition.

In such instances where fault detection circuitry 135 determines the presence of a fault condition, fault detection circuitry 135 measures the frequency values of the signal across the HRG assembly to determine the frequency 421 of the signal at the same time, with respect to time 423, corresponding to the spike in voltage of respective waveforms. As shown in waveform 440 of graphical representation 411, waveform 440 indicates a frequency 421 of approximately 20 Hz at the corresponding time. Accordingly, fault detection circuitry 135 performs a comparison between the frequency value and operational parameters of devices within the industrial automation environment (e.g., industrial devices 130) to determine a device operating at the frequency value (approximately 20 Hz), and a location of the device, corresponding to the fault condition. For example, the frequency value of waveform 440 may indicate that a fault has occurred at the load side of a bus supply, such as at fault detection area 226 of operating environment 200.

While FIGS. 4A, 4B, and 4C show specific examples of voltage, current, and frequency values, other values, measurements, and combinations and variations thereof may be used by a ground fault monitoring system to detect the presence and location of fault conditions within an environment.

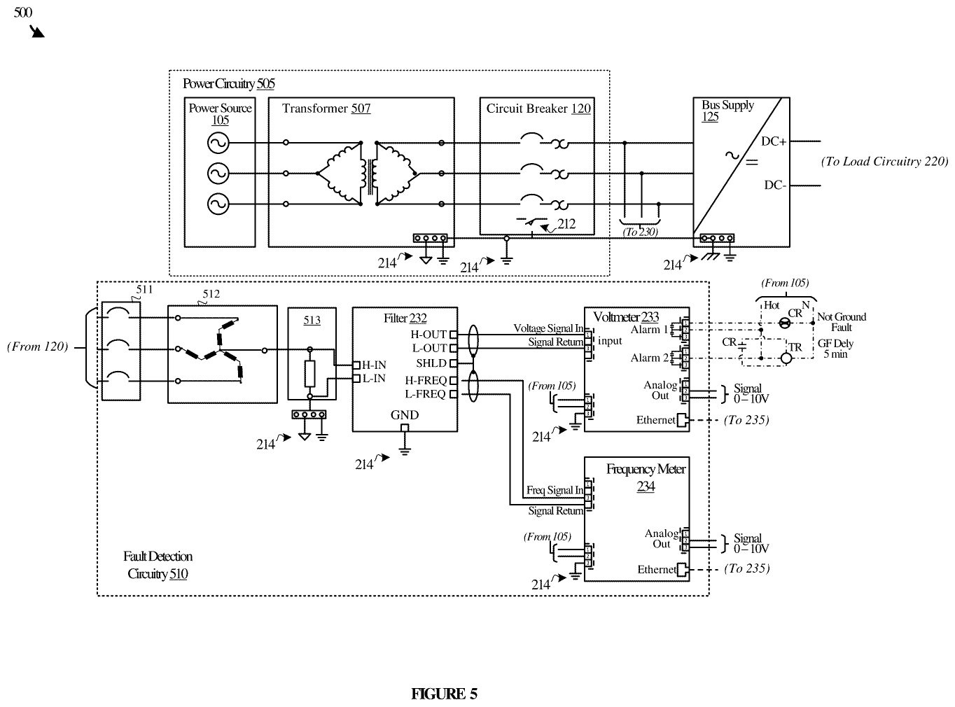

FIG. 5 illustrates an example block diagram of a ground fault monitoring system in accordance with some embodiments of the present technology, which references elements of operating environment 100 of FIG. 1 and operating environment 200 of FIG. 2. FIG. 5 shows operating environment 500, which is representative of an environment in which industrial and commercial processes may be performed. More specifically, operating environment 500 includes components operable in a floating power ground system. Operating environment 500 includes circuitry capable of generating power, converting and distributing power, and detecting fault conditions within the circuitry. More specifically, operating environment 500 includes power circuitry 505, bus supply 125, and fault detection circuitry 510.

Power circuitry 505 is representative of circuitry configurable to generate and convert power for use by various elements of operating environment 500. Power circuitry 505 includes power source 105, transformer 507, and circuit breaker 120.

Power source 105 is capable of providing three-phase AC power to transformer 507. Power source 105 includes three terminals, each coupled to a respective input terminal of transformer 507. In particular, a first terminal of power source 105 is coupled to a first input terminal of transformer 507 and provides a first phase of the three-phase AC power to transformer 507, a second terminal of power source 105 is coupled to a second input terminal of transformer 507 and provides a second phase of the three-phase AC power to transformer 507, and a third terminal of power source 105 is coupled to a third input terminal of transformer 507 and provides a third phase of the three-phase AC power to transformer 507.

Transformer 507 may be representative of a transformer having a delta-delta connection configuration. As such, transformer 507 includes a delta-connected primary side to which power source 105 is coupled, and a delta-connected secondary side to which circuit breaker 120 is coupled. In some embodiments, transformer 507 may be representative of another type of transformer or a transformer having a different connection configuration.

Circuit breaker 120 includes the three input terminals coupled to respective terminals of transformer 507 and includes three output terminals each coupled to a respective one of three input terminals of bus supply 125. Additionally, circuit breaker 120 includes switch 212, which may be utilized to connect or disconnect power circuitry 205 to and from bus supply 125, respectively. Switch 212 may be representative of a shunt switch that controls current flow through circuit breaker 120. For example, while switch 212 is closed, current can flow from transformer 507 to bus supply 125. If switch 212 is opened, such as in response to a fault condition at circuit breaker 120 or transformer 507, circuit breaker 120 shuts off and current flow is prevented from transformer 507 to bus supply 125. Accordingly, switch 212 may be controlled to allow or prevent current flow from power circuitry 505 to and from bus supply 125, respectively.

Bus supply 125 includes the three input terminals coupled to respective terminals of circuit breaker 120, a terminal coupled to ground node 214, and two output terminals coupled to load circuitry 220. Accordingly, bus supply 125 receives three-phase AC power as an input and provides DC power as an output to load circuitry 220. In some embodiments, bus supply 125, instead, outputs three-phase AC power to load circuitry 220.

Load circuitry 220 is representative of one or more industrial devices operable to perform respective functionality based on receiving power from bus supply 125. Examples of the industrial devices include variable-speed drives, motors, conveyer belts, circuit devices, programmable logic controllers (PLCs), relays, sensors, and more. While not explicitly shown in operating environment 500, load circuitry 220 may include multiple drives and motors, each configured to receive power from bus supply 125 and perform respective operations at different voltages, frequencies, and other operational parameters.

The output terminals of circuit breaker 120 may additionally be coupled to fault detection circuitry 510. Fault detection circuitry 510 is included in operating environment 500 to detect a presence and a location of a ground fault within power circuitry 505, bus supply 125, and load circuitry 220. Fault detection circuitry 505 includes circuit breaker 511, transformer 512, high-resistance ground (HRG) assembly 513, filter 232, voltmeter 233, and frequency meter 234. Voltmeter 233 and frequency meter 234 may be coupled to power source 105 (e.g., a single-phase 120V 5060 HZ voltage source), which may also provide power to ground fault output relays. Fault detection 510 may additionally include or be coupled to processing circuitry 235 in some embodiments.

In various embodiments, circuit breaker 511 is representative of a circuit breaker (e.g., solid-state circuit breaker, electromechanical circuit breaker) capable of providing protection from power circuitry 505 to fault detection circuitry 510. Circuit breaker 511 includes three input terminals, each coupled to a respective one of the three output terminals of circuit breaker 120, and three output terminals, each coupled to a respective one of three input terminals of transformer 512 of fault detection circuitry 510.

In various embodiments, transformer 512 is representative of an autotransformer having a zigzag connection configuration. As such, transformer 512 includes three input terminals coupled to the three output terminals of circuit breaker 511 and a single output terminal coupled to high-resistance ground (HRG) assembly 513. In some embodiments, transformer 512 may be representative of another type of transformer or a transformer having a different connection configuration.

HRG assembly 513 is representative of one or more high-resistance components (e.g., HRG assembly 231) positioned between a node of transformer 512 and ground node 214 to limit fault current and function as a source for detecting ground fault voltage and frequency signals. HRG assembly 513 includes a first terminal coupled to the output terminal of transformer 513 and a second terminal coupled to ground node 214.

Filter 232 is representative of circuitry capable of receiving ground fault voltage and frequency signals captured across HRG assembly 513 and filtering noise from the signals received at HRG assembly 513. Filter 232 is coupled to the first terminal of HRG assembly 513 and to the second terminal of HRG assembly 513 to receive the signals across HRG assembly 513. In various embodiments, filter 232 is configured to filter switching frequency noise from such signals, which may improve detection of voltage values and frequency values of such signals during fault detection processes. For example, filter 232 filters high pulse width modulation switching frequency noise, among other types of noise, including portions of signals having different frequencies. Filter 232 provides filtered signals to voltmeter 233 and 234 via output terminals coupled to respective input terminals of voltmeter 233 and 234.

Voltmeter 233 and frequency meter 234 are representative of sensors capable of measuring voltage and frequency values of the ground fault voltage and frequency signals filtered by filter 232. In various embodiments, frequency meter 234 is representative of a type of frequency detection sensor capable of detecting frequency values of a signal within a frequency range. In some embodiments, the frequency range detectable by frequency meter 234 includes low-frequency values, such as frequencies between one (1) Hertz (Hz) and 200 Hz. In some embodiments, the frequency range detectable by frequency meter 234 includes other frequency values, such as frequencies between ten (10) Hz and one-hundred and eighty (180) Hz. Additional or different frequency values and ranges thereof may also be detected by frequency meter 234. Voltmeter 233 and frequency meter 234 are further capable of providing measured signals to processing circuitry 235, such as by Ethernet connection, for processing thereof.

Processing circuitry 235 is representative of one or more processors, processing cores, or processing circuits capable of receiving the frequency and voltage values of the ground fault signals from voltmeter 233 and frequency meter 234, respectively, and detecting a presence and a location of a fault condition based on the values. Additionally, processing circuitry 235 may be capable of controlling operations of circuit breaker 120, among other elements of operating environment 200, via switch 212. Examples of such processor(s) of processing circuitry 235 include—but are not limited to—microcontrollers, microprocessors, general purpose processing units, central processing units (CPUs), graphical processing units (GPUs), digital signal processors (DSPs), application specific processors or circuits (e.g., ASICs), and logic devices (e.g., FPGAs), as well as any other type of processing device, combinations, or variations thereof.

To detect the presence of a fault condition in operating environment 500, processing circuitry 235 performs a comparison between the voltage values and a threshold voltage value and identifies a fault condition based on the results of the comparison. Similarly, to detect the location of the fault condition, such as one of power circuitry 505, bus supply 125, and load circuitry 220, processing circuitry 235 performs a comparison between the frequency values and operational parameters of each of the devices in operating environment 500. For example, devices of power circuitry 505 may operate at a frequency of approximately 60 Hz, bus supply 125 may operate at a frequency of approximately 180 Hz, and one or more motors of load circuitry 220 may operate at a frequency of approximately 20 Hz. Thus, for a given frequency value, processing circuitry 235 may correlate the fault condition with a matching operational frequency of a device in operating environment 500 and determine that the fault condition occurs at a location associated with the device.

Upon detecting a fault and the location of the fault, processing circuitry 235 may output an indication of the fault and the location of the fault. This may entail processing circuitry 235 displaying an indication (e.g., visual indication, graphical indication) of the fault and its location on a user interface of a computer, tablet, or smart phone, providing an alert to a user via the user interface or via a wireless connection to another computer, tablet, or smart phone, or the like. Additionally, processing circuitry 235 may trigger a disconnect option for power circuitry 505, such as opening switch 212 to prevent current flow from power circuitry 505 to bus supply 125.

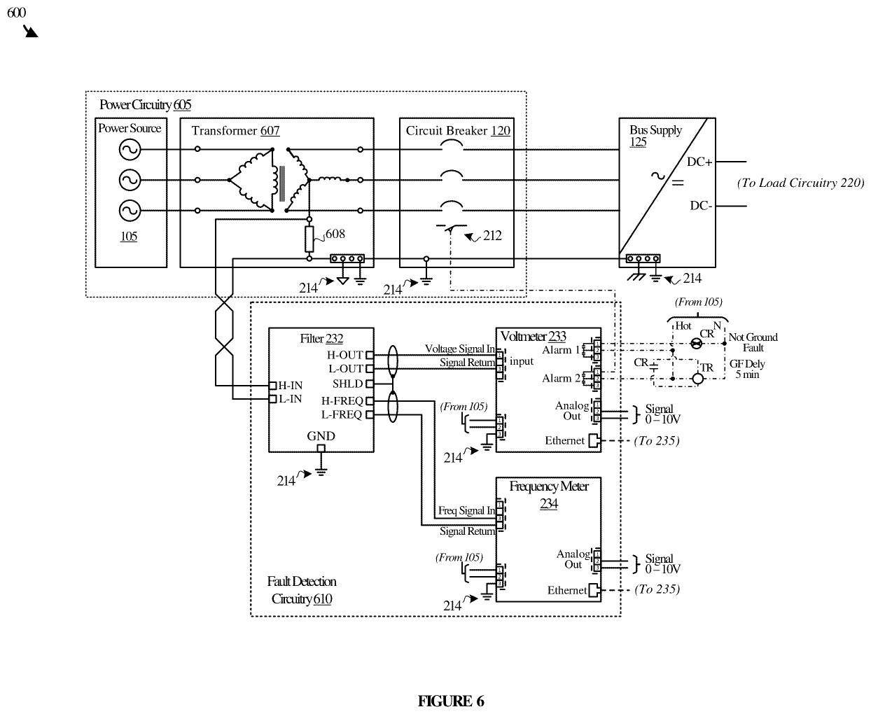

FIG. 6 illustrates an example block diagram of a ground fault monitoring system in accordance with some embodiments of the present technology, which references elements of operating environment 100 of FIG. 1 and operating environment 200 of FIG. 2. FIG. 6 shows operating environment 600, which is representative of an environment in which industrial and commercial processes may be performed. More specifically, operating environment 600 includes components operable in a high-resistance ground (HRG) grounding system. Operating environment 600 includes circuitry capable of generating power, converting and distributing power, and detecting fault conditions within the circuitry. More specifically, operating environment 600 includes power circuitry 605, bus supply 125, and fault detection circuitry 610.

Power circuitry 605 is representative of circuitry configurable to generate and convert power for use by various elements of operating environment 600. Power circuitry 605 includes power source 105, transformer 607, and circuit breaker 120.

Power source 105 is capable of providing three-phase AC power to transformer 607. Power source 105 includes three terminals, each coupled to a respective input terminal of transformer 607. In particular, a first terminal of power source 105 is coupled to a first input terminal of transformer 607 and provides a first phase of the three-phase AC power to transformer 607, a second terminal of power source 105 is coupled to a second input terminal of transformer 607 and provides a second phase of the three-phase AC power to transformer 607, and a third terminal of power source 105 is coupled to a third input terminal of transformer 607 and provides a third phase of the three-phase AC power to transformer 607.

Transformer 607 may be representative of a transformer having a delta-wye connection configuration. As such, transformer 607 includes a delta-connected primary side to which power source 105 is coupled, and a Y-connected secondary side to which circuit breaker 120 is coupled. In some embodiments, transformer 607 may be representative of another type of transformer or a transformer having a different connection configuration.

Additionally, transformer 607 includes a high-resistance ground (HRG) assembly 608 coupled to a neutral output terminal of the Y-connected primary side of transformer 607. HRG assembly 608 is representative of one or more high-resistance components (e.g., HRG assembly 231, HRG assembly 513) positioned between a neutral node of transformer 607 and ground node 214 to limit fault current and function as a source for detecting ground fault voltage and frequency signals. HRG assembly 608 includes a first terminal coupled to the neutral output terminal of transformer 607 and a second terminal coupled to ground node 214.

Circuit breaker 120 includes the three input terminals coupled to respective terminals of transformer 607 and includes three output terminals each coupled to a respective one of three input terminals of bus supply 125. Additionally, circuit breaker 120 includes switch 212, which may be utilized to connect or disconnect power circuitry 205 to and from bus supply 125, respectively. Switch 212 may be representative of a shunt switch that controls current flow through circuit breaker 120. For example, while switch 212 is closed, current can flow from transformer 607 to bus supply 125. If switch 212 is opened, such as in response to a fault condition at circuit breaker 120 or transformer 607, circuit breaker 120 shuts off and current flow is prevented from transformer 607 to bus supply 125. Accordingly, switch 212 may be controlled to allow or prevent current flow from power circuitry 605 to and from bus supply 125, respectively.

Bus supply 125 includes the three input terminals coupled to respective terminals of circuit breaker 120, a terminal coupled to ground node 214, and two output terminals coupled to load circuitry 220. Accordingly, bus supply 125 receives three-phase AC power as an input and provides DC power as an output to load circuitry 220. In some embodiments, bus supply 125, instead, outputs three-phase AC power to load circuitry 220.

Load circuitry 220 is representative of one or more industrial devices operable to perform respective functionality based on receiving power from bus supply 125. Examples of the industrial devices include variable-speed drives, motors, conveyer belts, circuit devices, programmable logic controllers (PLCs), relays, sensors, and more. While not explicitly shown in operating environment 600, load circuitry 220 may include multiple drives and motors, each configured to receive power from bus supply 125 and perform respective operations at different voltages, frequencies, and other operational parameters.

Fault detection circuitry 610 is included in operating environment 600 to detect a presence and a location of a ground fault within power circuitry 605, bus supply 125, and load circuitry 220. Fault detection circuitry 605 includes filter 232, voltmeter 233, and frequency meter 234. Fault detection 505 may additionally include or be coupled to processing circuitry 235 in some embodiments.

Fault detection circuitry 610 is coupled to power circuitry 605 to receive signals from power circuitry 605 and detect the presence and location of a ground fault based on the signals. More particularly, filter 232 of fault detection circuitry 610 is coupled to HRG assembly 608 of transformer 607. Filter 232 is representative of circuitry capable of receiving ground fault voltage and frequency signals captured across HRG assembly 608 and filtering noise from the signals received at HRG assembly 608. Filter 232 is coupled to the first terminal of HRG assembly 608 and to the second terminal of HRG assembly 608 to receive the signals across HRG assembly 608. In various embodiments, filter 232 is configured to filter switching frequency noise from such signals, which may improve detection of voltage values and frequency values of such signals during fault detection processes. For example, filter 232 filters high pulse width modulation switching frequency noise, among other types of noise, including portions of signals having different frequencies. Filter 232 provides filtered signals to voltmeter 233 and 234 via output terminals coupled to respective input terminals of voltmeter 233 and 234.

Voltmeter 233 and frequency meter 234 are representative of sensors capable of measuring voltage and frequency values of the ground fault voltage and frequency signals filtered by filter 232. In various embodiments, frequency meter 234 is representative of a type of frequency detection sensor capable of detecting frequency values of a signal within a frequency range. In some embodiments, the frequency range detectable by frequency meter 234 includes low-frequency values, such as frequencies between one (1) Hertz (Hz) and 200 Hz. In some embodiments, the frequency range detectable by frequency meter 234 includes other frequency values, such as frequencies between ten (10) Hz and one-hundred and eighty (180) Hz. Additional or different frequency values and ranges thereof may also be detected by frequency meter 234. Voltmeter 233 and frequency meter 234 are further capable of providing measured signals to processing circuitry 235, such as by Ethernet connection, for processing thereof.

Processing circuitry 235 is representative of one or more processors, processing cores, or processing circuits capable of receiving the frequency and voltage values of the ground fault signals from voltmeter 233 and frequency meter 234, respectively, and detecting a presence and a location of a fault condition based on the values. Additionally, processing circuitry 235 may be capable of controlling operations of circuit breaker 120, among other elements of operating environment 200, via switch 212. Examples of such processor(s) of processing circuitry 235 include—but are not limited to—microcontrollers, microprocessors, general purpose processing units, central processing units (CPUs), graphical processing units (GPUs), digital signal processors (DSPs), application specific processors or circuits (e.g., ASICs), and logic devices (e.g., FPGAs), as well as any other type of processing device, combinations, or variations thereof.

To detect the presence of a fault condition in operating environment 600, processing circuitry 235 performs a comparison between the voltage values and a threshold voltage value and identifies a fault condition based on the results of the comparison. Similarly, to detect the location of the fault condition, such as one of power circuitry 605, bus supply 125, and load circuitry 220, processing circuitry 235 performs a comparison between the frequency values and operational parameters of each of the devices in operating environment 600. For example, devices of power circuitry 605 may operate at a frequency of approximately 60 Hz, bus supply 125 may operate at a frequency of approximately 180 Hz, and one or more motors of load circuitry 220 may operate at a frequency of approximately 20 Hz. Thus, for a given frequency value, processing circuitry 235 may correlate the fault condition with a matching operational frequency of a device in operating environment 600 and determine that the fault condition occurs at a location associated with the device.

Upon detecting a fault and the location of the fault, processing circuitry 235 may output an indication of the fault and the location of the fault. This may entail processing circuitry 235 displaying an indication (e.g., visual indication, graphical indication) of the fault and its location on a user interface of a computer, tablet, or smart phone, providing an alert to a user via the user interface or via a wireless connection to another computer, tablet, or smart phone, or the like. Additionally, processing circuitry 235 may trigger a disconnect option for power circuitry 605, such as opening switch 212 to prevent current flow from power circuitry 605 to bus supply 125.

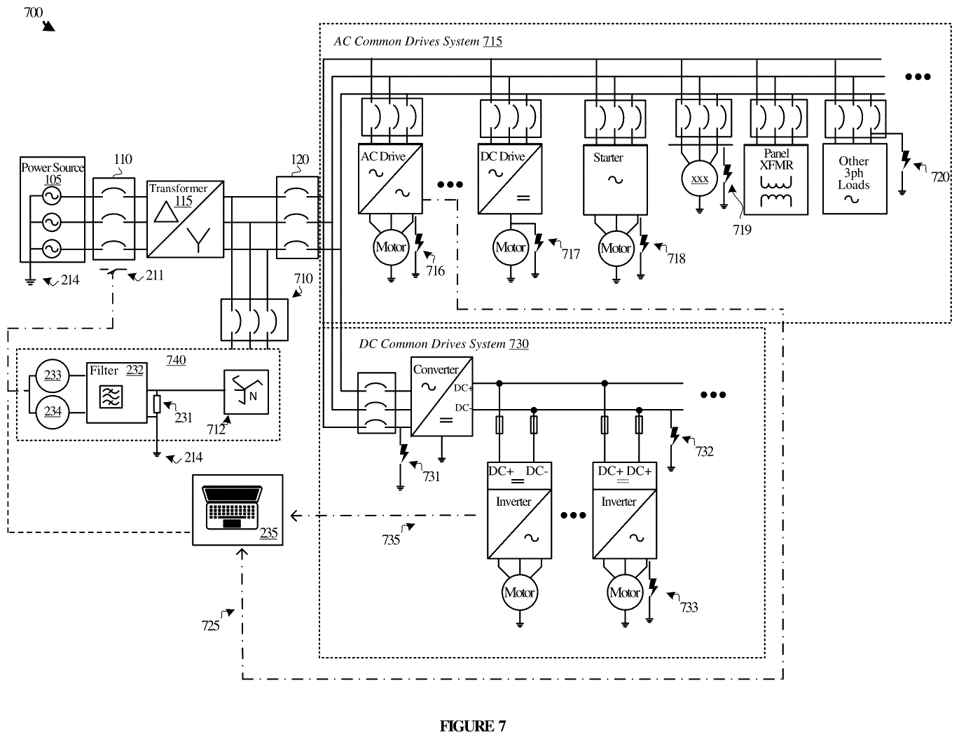

FIG. 7 illustrates an example block diagram of a ground fault monitoring system in accordance with some embodiments of the present technology, which references elements of operating environment 100 of FIG. 1 and operating environment 200 of FIG. 2. FIG. 7 shows operating environment 700, which is representative of an environment in which industrial and commercial processes may be performed. Operating environment 700 includes power source 105, circuit breaker 110, transformer 115, circuit breaker 120, circuit breaker 710, AC common bus drives system 715, DC common bus drives system 730, ground fault detection circuitry 740, and processing circuitry 235.

Like the systems shown in operating environments 200 of FIG. 2, 500 of FIG. 5, and 600 of FIG. 6, operating environment 700 shows an alternative embodiment in which ground fault detection circuitry 740 performs ground fault presence and location detection operations, such as those of process 300 of FIG. 3.

In operating environment 700, ground fault detection circuitry 740 includes HRG assembly 231, filter 232, voltmeter 233, and frequency meter 234 like ground fault detection circuitry 135, however, ground fault detection circuitry 740 additionally includes zig-zag component 712. Zig-zag component 712 is representative of a device organized in a zig-zag coupling configuration to interface with circuit breaker 710 and provide a neutral line at which HRG assembly 231 is coupled on a floating system. Ground fault detection circuitry 740 provides signals captured at HRG assembly 231 and filtered by filter 232 to processing circuitry 235. Processing circuitry 235 determines a presence of a fault condition and a location of the fault condition among various fault detection areas within operating environment 700 based on the signals provided by ground fault detection circuitry 740.

For example, processing circuitry 235 may determine that a fault condition has occurred on the line side of operating environment 700, such as at a location between power source 105 and circuit breaker 120, at an AC bus side of operating environment 700, such as at one or more of ground fault areas of AC common bus drives system 715 (e.g., ground fault areas 716, 717, 718, 719, or 720), and/or at a DC bus side of operating environment 700, such as one or more of ground fault areas of DC common bus drives system 730 (e.g., ground fault areas 731, 732, or 733).

In various embodiments, AC common bus drives system 715 is representative of a system of drives, starters, motors, and other loads and devices that utilize AC power from power source 105, while DC common bus drives system 730 is representative of a system of converters, inverters, and loads that utilize DC power converted from the AC power supplied by power source 105. One or more of the devices of each system may be coupled to processing circuitry 235 to provide frequency indications (e.g., frequency indication 725, frequency indication 735) to processing circuitry 235 to indicate an operational frequency of a respective device. Processing circuitry 235 may use the frequency indications to determine a corresponding location of a fault condition based on a comparison between the frequency indications and a frequency value of a signal indicative of a fault condition captured at HRG assembly 231.

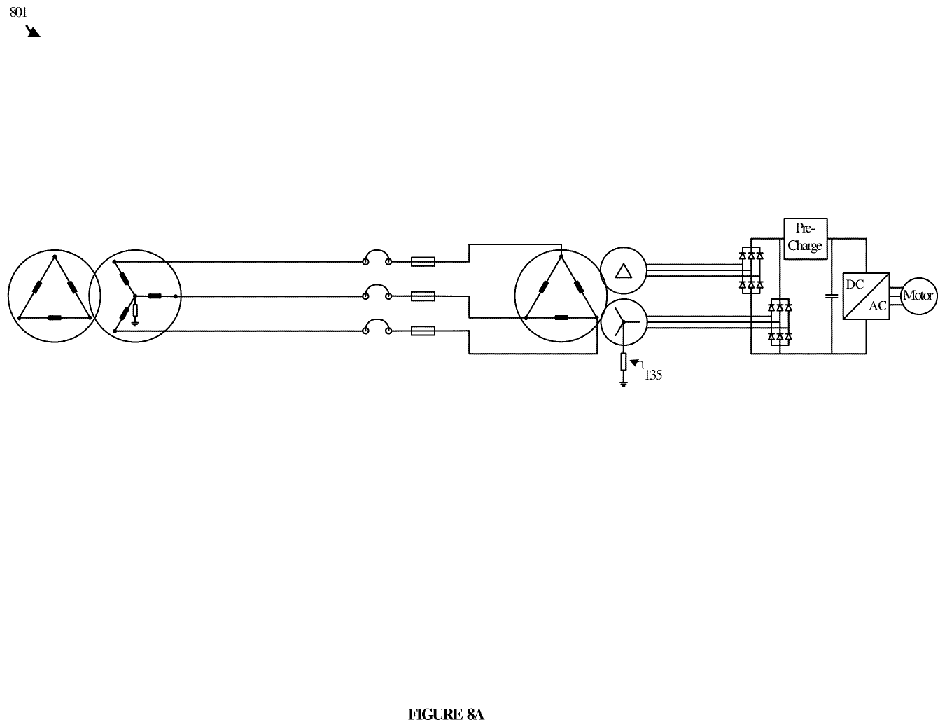

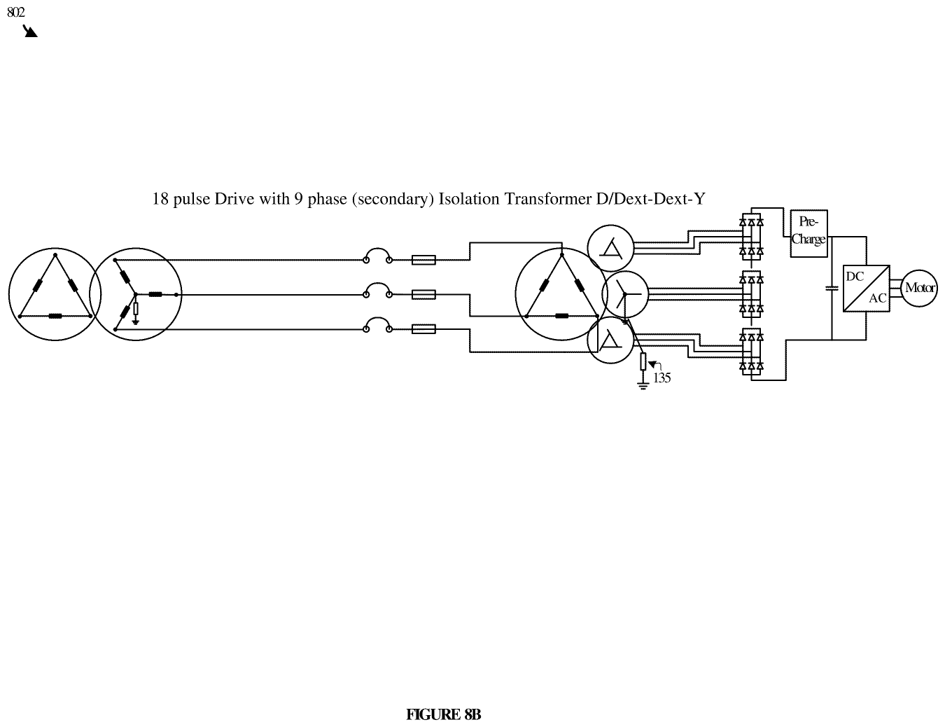

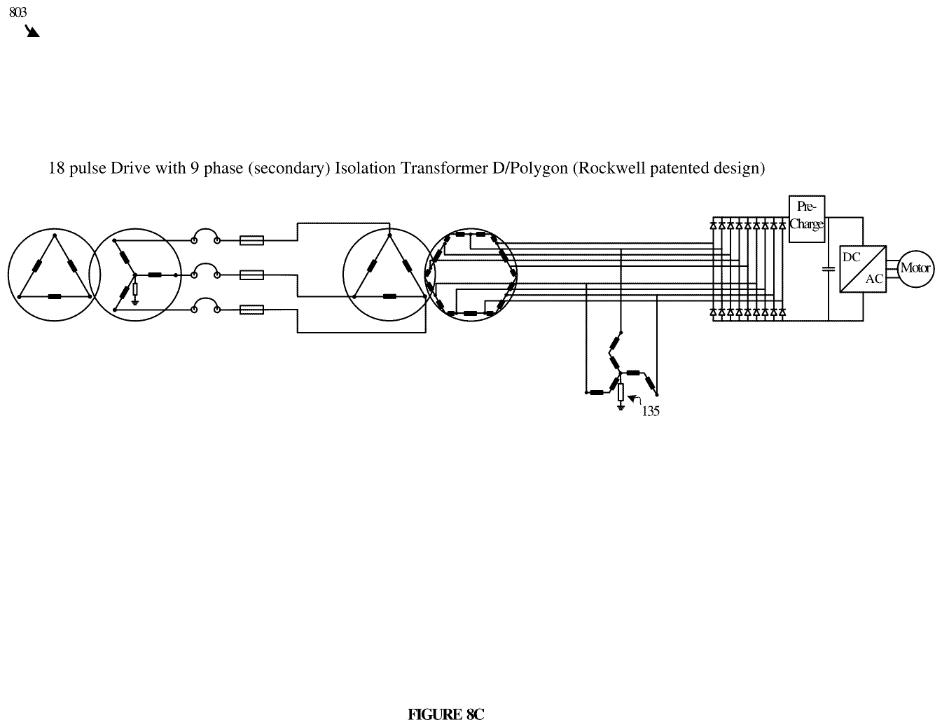

FIGS. 8A, 8B, and 8C illustrate example block diagrams of ground fault monitoring systems in accordance with some embodiments of the present technology, which include and reference elements of operating environment 100 of FIG. 1.

Referring first to FIG. 8A, FIG. 8A includes operating environment 801 representative of an environment in which commercial and industrial operations may be performed. More specifically, operating environment 801 shows a 12-pulse drive with a 6 phase isolation transformation in a delta/delta-wye configuration that feeds a bus system, and ultimately, a load (e.g., a motor). A neutral line of the wye-configured components of this drive may be coupled to ground fault detection system 135. Accordingly, ground fault detection system 135 can measure values within the drive and provide the values to processing circuitry (e.g., processing circuitry 235) for the detection of a fault condition and a location thereof within operating environment 801. Based on the drive being a 12-pulse drive, the processing circuitry may detect the location of the fault based on a multiple of the measured frequency at ground fault detection circuitry 135. For example, a signal measured by frequency meter 234 may include a 360 Hz frequency signature when power source 105 operates at 60 Hz.

Referring next to FIG. 8B, FIG. 8B includes operating environment 802 representative of an environment in which commercial and industrial operations may be performed. More specifically, operating environment 802 shows an 18-pulse drive with a 9 phase isolation transformation in a delta/delta/delta-wye configuration that feeds a bus system, and ultimately, a load (e.g., a motor). A neutral line of the wye-configured components of this drive may be coupled to ground fault detection system 135. Accordingly, ground fault detection system 135 can measure values within the drive and provide the values to processing circuitry (e.g., processing circuitry 235) for the detection of a fault condition and a location thereof within operating environment 802. Based on the drive being an 18-pulse drive, the processing circuitry may detect the location of the fault based on a multiple of the measured frequency at ground fault detection circuitry 135. For example, a signal measured by frequency meter 234 may include a 540 Hz frequency signature when power source 105 operates at 60 Hz.

Referring next to FIG. 8C, FIG. 8C includes operating environment 803 representative of an environment in which commercial and industrial operations may be performed. More specifically, operating environment 803 shows an 18-pulse drive with a 9 phase isolation transformation in a delta/polygon configuration that feeds a bus system, and ultimately, a load (e.g., a motor). A neutral line of the wye-configured components of this drive coupled to an output of the polygon-configured components may be coupled to ground fault detection system 135. Accordingly, ground fault detection system 135 can measure values within the drive and provide the values to processing circuitry (e.g., processing circuitry 235) for the detection of a fault condition and a location thereof within operating environment 803. Based on the drive being an 18-pulse drive, the processing circuitry may detect the location of the fault based on a multiple of the measured frequency at ground fault detection circuitry 135. For example, a signal measured by frequency meter 234 may include a 540 Hz frequency signature when power source 105 operates at 60 Hz.

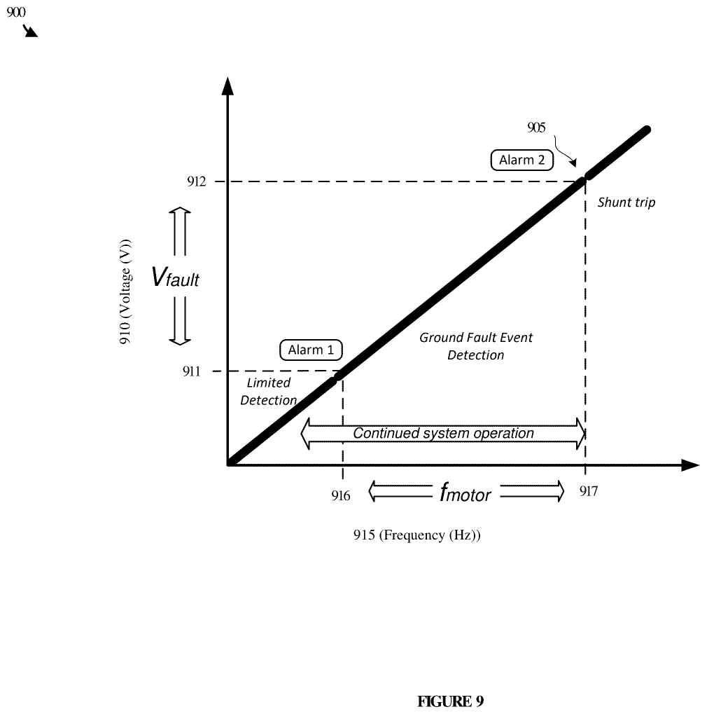

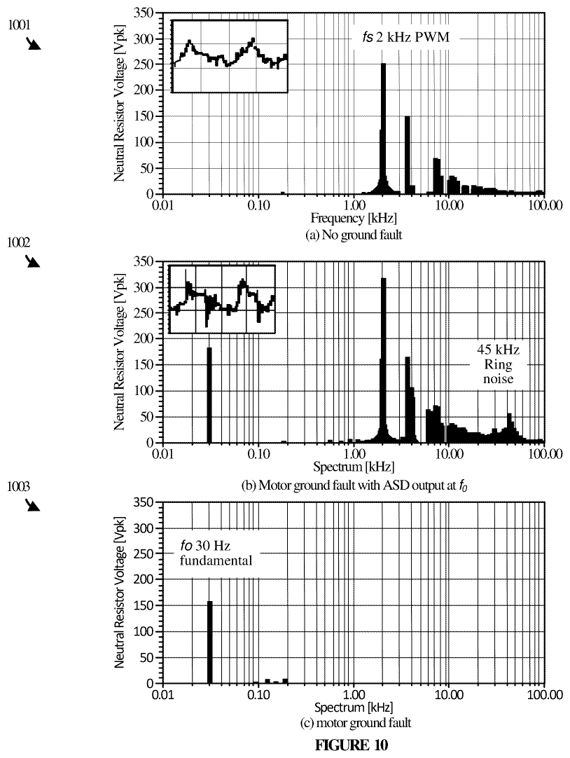

FIGS. 9 and 10 illustrate example graphical representations related to noise filtering in a ground fault monitoring system in accordance with some embodiments of the present technology, which reference elements of operating environment 100 of FIG. 1 and operating environment 200 of FIG. 2.

Referring first to FIG. 9, FIG. 9 shows graphical representation 900, which includes waveform 905 with respect to voltage 910 and frequency 915. Waveform 905 is representative of a signal indicative of a ground fault event and detection thereof relative to voltage and frequency, which may be performed by ground fault detection circuitry 135 and processing circuitry 235. More specifically, when waveform 905 includes a low frequency (e.g., below 5 Hz) below frequency threshold 916 and a low voltage below voltage threshold 911, the ability for processing circuitry 235 to detect a presence and location of a fault event may be limited due to sensor limitations, for example. More particularly, waveform 905 show a signal representative of an a neutral RMS voltage having a corresponding linear relationship to a fundamental frequency (e.g., motor frequency) associated with an AC motor.

As waveform 905 increases with respect to voltage 910 and frequency 915, such as between voltage threshold 911 and voltage threshold 912, and between frequency threshold 916 and frequency threshold 917, respectively, processing circuitry 235 monitors waveform 905 for a breach of voltage threshold 912 and/or frequency threshold 917. Upon waveform 905 exceeding the thresholds, processing circuitry 235 can detect the presence of a fault event based on the voltage of waveform 905 and the location of the fault event based on the frequency of waveform 905. After detecting the presence and location of a fault event, processing circuitry 235 may initiate protective operations to cut power to fault devices, such as by tripping a shunt switch (e.g., switch 211). Voltage threshold 912 may be an alarm threshold corresponding to a highest operating point to ensure fault detection of a device in the environment. For example, for an AC motor running at any commanded frequency in the range under a direct zero impedance, a fault detection system may measure its voltage and frequency at a corresponding output line-neutral coupled at HRG assembly 231. If the signal measured from a fault at fault area 226 has some impedance (Zfault), then voltage across HRG assembly 231 may be divided between Zfault and NGR values. Thus, to detect a fault under all fault impedance conditions and operating frequency conditions, voltage threshold 911 may be set as low as possible to initiate a fault detection process.

Processing circuitry 235 may be capable of detecting a fault event even at low frequencies when fundamental line-neutral voltage is low, such as at single-digit frequencies at or above frequency threshold 916, based on filtering capabilities of filter 232, which is represented next in FIG. 10. FIG. 10 shows graphical representations 1001, 1002, and 1003, each of which show signals captured across HRG assembly 231 with respect to voltage and frequency during operation of an industrial automation system. More specifically, graphical representation 1001 shows a signal captured at HRG assembly 231 with respect to voltage and frequency when no ground fault is present in the industrial automation system. Graphical representation 1002 shows a signal captured at HRG assembly 231 with respect to voltage and frequency when a ground fault is detected at a motor of the industrial automation system (e.g., at fault detection area 226 of operating environment 200). Graphical representation 1003 shows the signal captured and shown in graphical representation 1002 which has been filtered by filter 232.

Without filtering high frequency PWM switching noise, common mode noise, charging cable noise, and the like, the signals captured at HRG assembly 231 may include ringing and high-frequency noise values that may make fault detection difficult. However, filter 232 is included in fault detection circuitry 135 to remove such noise such that processing circuitry 235 can receive and process a fundamental frequency of the signals with reduced noise compared to non-filtered implementations. This may advantageously improve fault presence and location detection, including at low frequencies.

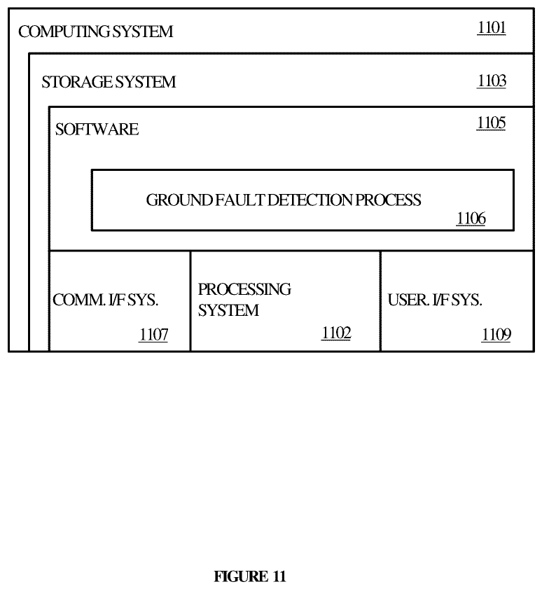

FIG. 11 illustrates computing system 1101 to perform fault detection processes according to an implementation of the present technology. Computing system 1101 is representative of any system or collection of systems with which the various operational architectures, processes, scenarios, and sequences disclosed herein for fault detection and fault monitoring may be employed. Computing system 1101 may be implemented as a single apparatus, system, or device or may be implemented in a distributed manner as multiple apparatuses, systems, or devices. Computing system 1101 includes, but is not limited to, processing system 1102, storage system 1103, software 1105, communication interface system 1107, and user interface system 1109 (optional). Processing system 1102 is operatively coupled with storage system 1103, communication interface system 1107, and user interface system 1109. Computing system 1101 may be representative of a cloud computing device, distributed computing device, or the like.

Processing system 1102 loads and executes software 1105 from storage system 1103. Software 1105 includes and implements ground fault detection process 1106, which is representative of any of the fault detection, fault condition processing, signal measuring and processing, device testing and analysis, and other processes discussed with respect to the preceding Figures. When executed by processing system 1102 to provide fault detection functions, software 1105 directs processing system 1102 to operate as described herein for at least the various processes, operational scenarios, and sequences discussed in the foregoing implementations. Computing system 1101 may optionally include additional devices, features, or functionality not discussed for purposes of brevity.

Referring still to FIG. 11, processing system 1102 may comprise a micro-processor and other circuitry that retrieves and executes software 1105 from storage system 1103. Processing system 1102 may be implemented within a single processing device but may also be distributed across multiple processing devices or sub-systems that cooperate in executing program instructions. Examples of processing system 1102 include general purpose central processing units, graphical processing units, application specific processors, and logic devices, as well as any other type of processing device, combinations, or variations thereof.

Storage system 1103 may comprise any computer readable storage media readable by processing system 1102 and capable of storing software 1105. Storage system 1103 may include volatile and nonvolatile, removable and non-removable media implemented in any method or technology for storage of information, such as computer readable instructions, data structures, program modules, or other data. Examples of storage media include random access memory, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 1103 may also include computer readable communication media over which at least some of software 1105 may be communicated internally or externally. Storage system 1103 may be implemented as a single storage device but may also be implemented across multiple storage devices or sub-systems co-located or distributed relative to each other. Storage system 1103 may comprise additional elements, such as a controller, capable of communicating with processing system 1102 or possibly other systems.

Software 1105 (including ground fault detection process 1106) may be implemented in program instructions and among other functions may, when executed by processing system 1102, direct processing system 1102 to operate as described with respect to the various operational scenarios, sequences, and processes illustrated herein. For example, software 1105 may include program instructions for implementing a fault monitoring and a fault detection process as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 1105 may include additional processes, programs, or components, such as operating system software, virtualization software, or other application software. Software 1105 may also comprise firmware or some other form of machine-readable processing instructions executable by processing system 1102.

In general, software 1105 may, when loaded into processing system 1102 and executed, transform a suitable apparatus, system, or device (of which computing system 1101 is representative) overall from a general-purpose computing system into a special-purpose computing system customized to provide device health metrics and contextualization and instantiation thereof as described herein. Indeed, encoding software 1105 on storage system 1103 may transform the physical structure of storage system 1103. The specific transformation of the physical structure may depend on various factors in different implementations of this description. Examples of such factors may include, but are not limited to, the technology used to implement the storage media of storage system 1103 and whether the computer-storage media are characterized as primary or secondary storage, as well as other factors.

For example, if the computer readable storage media are implemented as semiconductor-based memory, software 1105 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 1107 may include communication connections and devices that allow for communication with other computing systems (not shown) over communication networks (not shown). Examples of connections and devices that together allow for inter-system communication may include network interface cards, antennas, power amplifiers, radiofrequency circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing system 1101 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of networks, or variation thereof. The aforementioned communication networks and protocols are well known and need not be discussed at length here.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112 (f) will begin with the words “means for” but use of the term “for” in any other context is not intended to invoke treatment under 35 U.S.C. § 112 (f). Accordingly, the applicant reserves the right to pursue additional claims after filing this application to pursue such additional claim forms, in either this application or in a continuing application.

What is claimed is:

1. A ground fault monitoring system comprising:
fault detection circuitry configured to:
identify a signal including a non-zero voltage indicative of a fault condition in an industrial automation environment, and
provide the signal to processing circuitry; and
the processing circuitry configured to:
identify a frequency value of the signal; and
determine which location among locations, including a power supply location, a power bus location, and a load location, in the industrial automation environment corresponds to the fault condition based on performing a comparison between the frequency value of the signal and operational parameters of devices at the locations in the industrial automation environment.

2. The ground fault monitoring system of claim 1, wherein the fault detection circuitry comprises a ground-fault resistor assembly, a ground-fault signal filter, and one or more sensors.

3. The ground fault monitoring system of claim 2, wherein the fault detection circuitry is configured to identify the signal at the ground-fault resistor assembly and filter noise of the signal based on filtering high pulse width modulation switching frequency noise via the ground-fault signal filter.

4. The ground fault monitoring system of claim 3, wherein to identify the frequency value of the signal, the processing circuitry is configured to read the frequency value from a frequency sensor of the one or more sensors, wherein the frequency sensor is configured to measure the frequency value of the signal within a range of frequencies.

5. The ground fault monitoring system of claim 3, wherein the fault detection circuitry is configured to filter the noise of the signal based further on filtering common mode noise and charging cable noise via the ground-fault signal filter.

6. The ground fault monitoring system of claim 1, wherein the power supply location comprises an alternating current (AC) power supply configured to operate at a first frequency and provide AC power to the power bus location.

7. The ground fault monitoring system of claim 6, wherein the power bus location comprises a direct current (DC) bus configured to operate at a second frequency and provide DC power to the load location.

8. The ground fault monitoring system of claim 7, wherein the load location comprises one or more motors each configured to operate at one or more frequencies different from the first frequency and the second frequency.

9. The ground fault monitoring system of claim 8, wherein the processing circuitry is further configured to:
for the frequency value of the signal corresponding to the load location, determine which motor of the one or more motors corresponds to the fault condition based on performing the comparison between the frequency value of the signal and the operational parameters of the one or more motors; and
for results of the comparison indicating two motors of the one or more motors:
change an operating frequency of one of the two motors,
identify the frequency value of the signal in response to changing the operating frequency of the one of the two motors, and
determine which of the two motors corresponds to the fault condition based on performing a further comparison between the frequency value of the signal and the operating frequency of the one of the two motors.

10. The ground fault monitoring system of claim 1, wherein the processing circuitry is further configured to output an indication of the fault condition and the corresponding location.

11. A ground fault monitoring system comprising:
power supply circuitry coupled to bus circuitry and fault detection circuitry and configured to provide alternating current (AC) power to the bus circuitry;
the bus circuitry coupled to load circuitry and the fault detection circuitry and configured to convert the AC power to direct current (DC) power and provide the DC power to the load circuitry;
the load circuitry coupled to the fault detection circuitry; and
the fault detection circuitry configured to:
identify a signal including a non-zero voltage indicative of a fault condition,
identify a frequency value of the signal, and
determine which one of the power supply circuitry, the bus circuitry, and the load circuitry corresponds to the fault condition based on performing a comparison between the frequency value of the signal and operational parameters of devices among the power supply circuitry, the bus circuitry, and the load circuitry.

12. The ground fault monitoring system of claim 11, wherein the fault detection circuitry comprises a ground-fault resistor assembly, a ground-fault signal filter, one or more sensors, and processing circuitry.

13. The ground fault monitoring system of claim 12, wherein the fault detection circuitry is configured to identify the signal at the ground-fault resistor assembly and filter noise of the signal based on filtering high pulse width modulation switching frequency noise via the ground-fault signal filter.

14. The ground fault monitoring system of claim 13, wherein to identify the frequency value of the signal, the processing circuitry is configured to read the frequency value from a frequency sensor of the one or more sensors, wherein the frequency sensor is configured to measure the frequency value of the signal within a range of frequencies.

15. The ground fault monitoring system of claim 13, wherein the fault detection circuitry is configured to filter the noise of the signal based further on filtering common mode noise and charging cable noise via the ground-fault signal filter.

16. The ground fault monitoring system of claim 11, wherein the power supply circuitry, the bus circuitry, and the load circuitry are each configured to operate at different frequency values relative to one another.

17. A method comprising:
by fault detection circuitry in an industrial automation environment:
identifying a signal including a non-zero voltage indicative of a fault condition in the industrial automation environment including power supply circuitry, bus circuitry, load circuitry, and the fault detection circuitry;
identifying a frequency value of the signal; and
determining which one of the power supply circuitry, the bus circuitry, and the load circuitry corresponds to the fault condition based on performing a comparison between the frequency value of the signal and operational parameters of devices among the power supply circuitry, the bus circuitry, and the load circuitry.

18. The method of claim 17, wherein identifying the frequency value of the signal comprises filtering noise of the signal based on filtering high pulse width modulation switching frequency noise of the signal, and identifying the frequency value of the filtered signal.

19. The method of claim 18, wherein identifying the frequency value of the filtered signal comprises filtering the noise of the signal based further on filtering common mode noise and charging cable noise of the signal.

20. The method of claim 17, wherein the power supply circuitry, the bus circuitry, and the load circuitry are each configured to operate at different frequency values relative to one another.
